(19) United States
(12) Patent Application Publication
(10) Pub. No.: US 2014/0010952 A1
(43) Pub. Date: Jan. 9, 2014

(54) PCB REPAIR OF DEFECTIVE INTERCONNECTS BY DEPOSITION OF CONDUCTIVE INK

(71) Applicant: Noam ROSENSTEIN, Afula (IL)

(72) Inventor: Noam ROSENSTEIN, Afula (IL)

(21) Appl. No.: 13/726,569

(22) Filed: Dec. 25, 2012

Related U.S. Application Data
(60) Provisional application No. 61/582,417, filed on Jan. 2, 2012.

(51) Int. Cl. H05K 3/00; H05K 3/12

(52) U.S. Cl. CPC H05K 3/0085; H05K 3/125
USPC 427/8; 118/696

(57) ABSTRACT

There may be provided a system that may include a computer arranged to process images of areas of missing conductive material defects of an electrical circuit and to determine a defect correction scheme that defines a manner in which at least one of the missing conductive material defects should be amended; and
a conductive ink printer arranged to print conductive ink, in response to the defect correction scheme, to repair the at least one of the missing conductive material defects.

### RELATED APPLICATIONS

This application claims the benefit of U.S. provisional patent Ser. No. 61/582,417, filing date Jan. 2, 2012, which is incorporated herein by reference.

### BACKGROUND

An essential part of electronic devices is the circuit board which contains the functional parts. The parts have to be interconnected to achieve the required functionality of the device. Generally, these interconnections are made of a conductive material such as copper placed on a substrate and patterned into traces and other shapes according to design requirements. The various patterns have geometric characteristics in all three dimensions in order to provide the necessary performance.

During a Printed Circuit Board (PCB) production various defects can occur. These defects may be the result of unwanted additional or from missing conductive material thereby disrupting the flow of electricity. Since the most common conductive material is copper, this document will refer to it, though it should be understood that “copper” could be replaced by any other conductive material used in the industry for the purpose.

The removal of unwanted additional copper can be handled easily by the operator during verification using simple tools such as scalpel. Removal of excess copper can also be done by automated machinery. A laser ablation device, for example, can remove such excess copper once identified and located by an inspection device.

Partially or completely missing copper has to be added using a functionally similar conductive material. The added material has to be physically placed in such a way as to mimic the physical and electrical characteristics of the missing original copper.

Fixing the missing copper is usually done in an additional station with specific tools, operated by a skilled operator.

There is a growing need to provide efficient methods and systems for repair especially where expensive electronic circuitry is involved.

Examples of devices and manufacturing technologies where such repair is beneficial:
PCB fine-line production lines manufacturing PCBs with features having lines or spaces (L/S) dimensions of 12-50 micron.
High density interconnect substrates.
Via exposers—buildup pillars.
Interconnect bumps.
Photo voltage solar cells conductors.
Panels produced from a large number of layers (typically 50-60 layers).
Medical sensors chip.

Some of the manufacturing technologies mentioned above use very fine features and are extremely susceptible to malfunctioning if all spatial characteristics of the interconnects are not maintained.

In addition to the obvious defect of completely missing copper, inappropriate local thickness variations called “dish-downs”, partially missing copper or dents called “mouse bites”, traces thinner than the specification (possibly due to over etching) need to be repaired before proceeding to the ensuing production stages. FIG. 1 includes a top view of a first copper conductor 1 that exhibits a mouse bite defect 2, a partially missing copper defect 3 resulting from over etching and an open circuit 4 resulting from lack of copper. FIG. 1 also includes a three dimensional view of a second conductor 5 that exhibits a dishdown defect 6 that causes the second conductor to be thinner that desired at certain points.

In addition to the above, certain manufacturing technologies use solder balls or “bumps” to allow connecting electronic devices to the circuit boards. These bumps are made of conductive material and protrude above the circuit board in order to facilitate connecting the landing pads of the device to the landing pads of the circuit board. All bumps pertaining to a specific device have to be the same height and have the same outline in order to make proper connection. Any deviation in height or outline may result in a defective connection.

A prior art manufacturing process of solder bumps includes (a) creating integrated circuits (chips) on a wafer and metalizing pads on the surface of the integrated circuit, (b) depositing solder drops on each pad, (c) flipping the chips and positioning the chips in a manner that the pads are aligned with connectors of an external circuitry that should be connected to the pads; (d) re-melting the solder pads, and (e) filling gaps between the chips and the external circuitry with an electrically isolating adhesive.

Conductive material needs to be appropriately added to repair defective bumps. In addition to repairing defective conductive solder balls, insulating material may need to be added if detected missing.

There are provided methods and systems to perform said repairs.

### SUMMARY OF THE INVENTION

Systems and methods may be provided to selectively repair defects of interconnects found on printed circuit boards (PCB) or any other substrates with missing conductive materials defects. The PCB may be but is not limited to an interconnecting substrate for a semiconductor device, a functional circuit on which multiple components are to be placed or a panel with multiple functional circuits. The PCB may have various geometrical characteristics including but not limited to very fine details, small and large features, interconnects of various thickness, functional characteristics that depend on the geometry and materials used.

According to an embodiment of the invention defects caused by missing conductive material that may completely or partially disrupt the operation of the circuit are repaired. It is noted that a defect can be deemed as a defect that can not be repaired—for example—when an substantial (and/or long) amount of conductive material is missing or whenever the gap can not be bridged in an adequate manner.

According to an embodiment of the invention there may be provided a system that may include a computer arranged to process images of areas of missing conductive material defects of an electrical circuit and to determine a defect correction scheme that defines a manner in which at least one of the missing conductive material defects should be amended; and a conductive ink printer arranged to print conductive ink, in response to the defect correction scheme, to repair the at least one of the missing conductive material defects.

The system may include an image sensor arranged to acquire the images of the areas of missing conductive materials defects.

The conductive ink printer may be arranged to: select, based upon the defect correction scheme, a selected conductive ink out of multiple conductive inks that differ from each other and are accessible to the conductive ink printer; and print the selected conductive ink so as to treat one of the missing conductive material defects. The selection can be done in response to commands sent by the computer.

The conductive ink printer may include multiple print heads, wherein different print heads are used for printing different conductive inks. The different conductive inks differ from each other by conductivity and/or viscosity and/or other physical or chemical characteristics.

The conductive ink printer may be arranged to print multiple layers of at least one conductive ink to repair a missing conductive material defect.

The computer may be arranged to declare a missing conductive material defect as non-repairable.

The system may include a treatment module for at least partially treating a conductive ink that was printed on the electrical circuit.

The conductive ink printer may be arranged to print multiple layers of at least one conductive ink to repair a missing conductive material defect; and wherein the treatment module may be arranged to at least partially treat a conductive ink layer before printing another conductive ink layer.

The system may be adapted to perform a verification process to determine that the one or more missing conductive material defect was repaired.

The conductive ink printer may be further arranged to print conductive ink and non-conductive ink, in response to the defect correction scheme.

According to various embodiments of the invention a method may be provided and may include processing, by a computer, images of areas of missing conductive material defects of an electrical circuit and determining a defect correction scheme that defines a manner in which at least one of the missing conductive material defects should be amended; printing, by a conductive ink printer, conductive ink, in response to the defect correction scheme, to repair the at least one of the missing conductive material defects.

The method further may include acquiring, by an image sensor, the images of the areas of missing conductive materials.

The method may include selecting, based upon the defect correction scheme, a selected conductive ink out of multiple conductive inks that differ from each other and are accessible to the conductive ink printer, and printing the selected conductive ink so as to treat one of the missing conductive material defects.

The printing may include or may be preceded by selecting a print head out of multiple print heads of the conductive ink printer, wherein different print heads are used for printing different conductive inks. The different conductive inks may differ from each other by conductivity and/or viscosity and/or other physical or chemical characteristics.

The method may include printing multiple layers of at least one conductive ink to repair a missing conductive material defect.

The method may include declaring a missing conductive material defect as non-repairable.

The method may include at least partially treating a conductive ink that was printed on the electrical circuit.

The method may include printing multiple layers of at least one conductive ink to repair a missing conductive material defect; and at least partially treating a conductive ink layer before printing another conductive ink layer.

The method may include performing a verification process to determine that the one or more missing conductive material defect was repaired.

The method may include printing conductive ink and non-conductive ink, in response to the defect correction scheme.

It is understood that the methods and the systems are not limited to the embodiment examples described above, and my have more differing configurations.

### BRIEF DESCRIPTION OF THE DRAWINGS

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

FIG. 1 illustrates prior art missing copper defects;

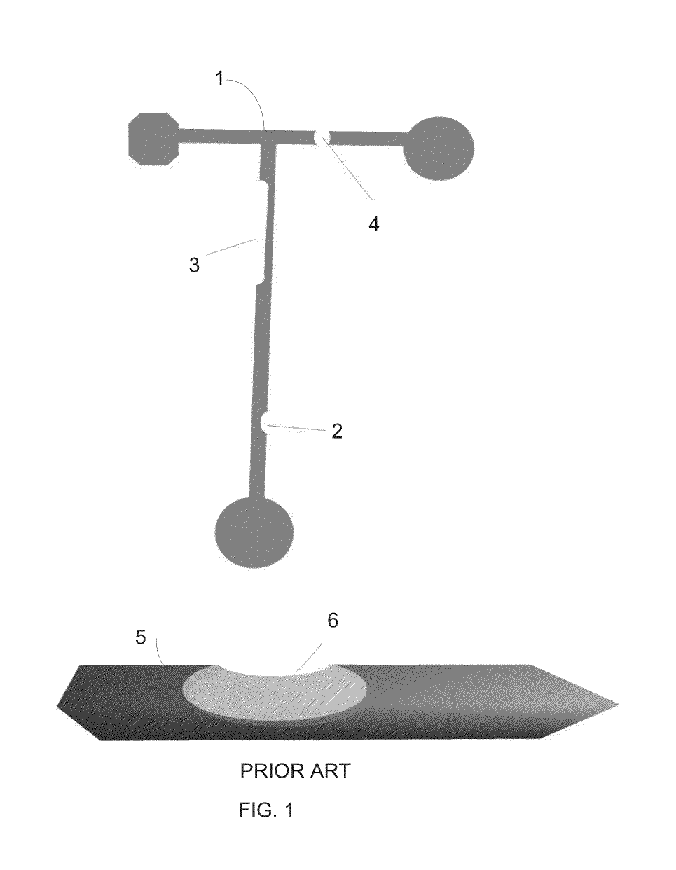

FIG. 2 illustrates a system, according to an embodiment of the invention.

FIG. 3 illustrates a system according to an embodiment of the invention;

FIG. 4 illustrates a system according to an embodiment of the invention;

FIG. 5 illustrates a system according to an embodiment of the invention; and

FIG. 6 illustrates a method according to an embodiment of the invention.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

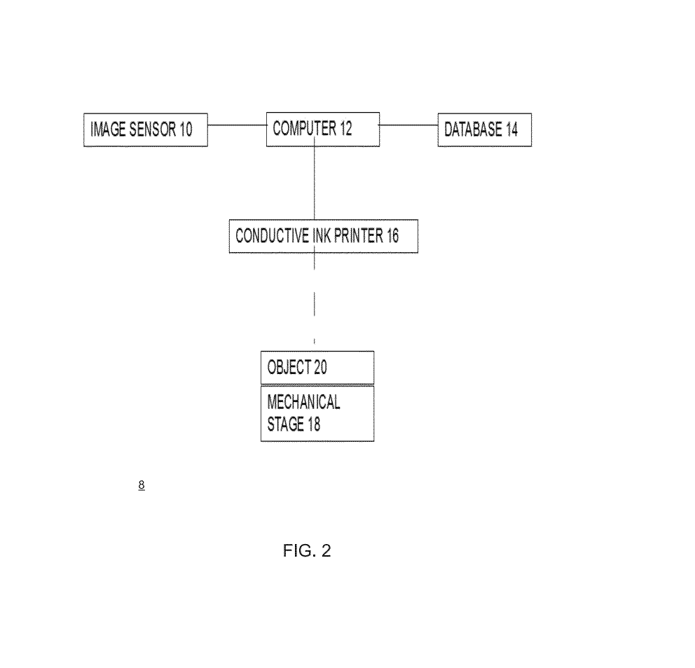

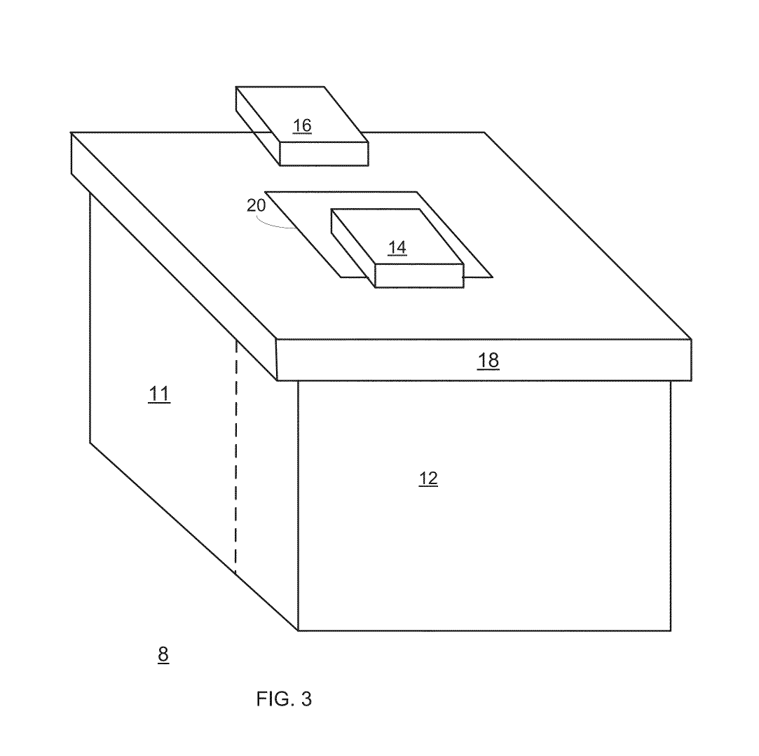

FIGS. 2 and 3 illustrate a system 8 according to an embodiment of the invention. System 8 may include a computer 12, an image sensor 10, a conductive ink printer 16, a storage device for storing database 14, and a mechanical stage 18 for supporting and moving object 20. The conductive ink printer 16 can print one or more conductive inks and may also print one or more isolating (non-conductive) inks. FIG. 3 also illustrates a printing support unit 11.

The conductive ink printer 16 may be controlled by the computer 12.

The computer may be arranged to analyze images of the object 20 acquired by the image sensor 10.

The analysis may include:
a. (a) Finding one or more missing material defects by, for example, comparing these images to reference images or information indicative of a desired shape and size of the object stored in database 14, comparing these images to each other,
b. Determining that one or more corrective actions should be taken to correct the one or more defects and the determination can be represented by a defect correction scheme. The defect correction scheme can be a set of instructions or commands aimed to a conductive ink printer, to a mechanical stage, to an image sensor, to a treatment module and the like.
c. Participating in (for example—triggering, controlling and the like) the one or more corrective actions. The one or more corrective actions may include printing a conductive ink (performing a conductive ink deposition).

According to another embodiment of the invention one or more corrective actions may include printing isolating (non-conductive) ink and may include a combination of conductive and isolating ink. The isolating ink can be printed by the conductive ink printer 16 or by an additional printer. The isolating ink can be printed to compensate form an absence of an isolating material. For example—a non-conductive ink can form a base on which the conductive ink is printed. Yet for another example—the non-conductive ink can coat a previously printed conductive ink.

If arranged to print different materials (all conductive or some conductive and some isolating) the conductive ink printer 16 can have different print heads that are allocated for printing different materials that may differ from each other by one or more property.

According to another embodiment of the invention system 8 does not optically acquire the images (may not have image sensor 10) and may store in database 14 images obtained from another system.

According to an embodiment of the invention the image sensor 10 may be replaced by a full inspection device.

Yet according to another embodiment of the invention the system 8 does not store data base 14 and the database 14 can be stored in another system such as another system that has full computer aided design or computer aided manufacturing (CAD/CAM) functionality.

Referring back to FIGS. 2 and 3 the mechanical stage 18 can move the object 20 in relation to the image sensor 10 and to the conductive ink printer 16. It is noted that the image sensor 10 can be moved in relation to the object 20. The same may apply to the conductive ink printer 16.

The conductive ink printer 16 may have one or more printing modules (such as print heads) that are capable of printing several types of materials. The materials may be conductive or insulating based on the necessary repair. They may also have various chemical compositions and properties.

For example, the conductive inks can be silver based inks, carbon black based inks, carbon based inks or copper based inks although silver based copper based conductive inks may tend to oxidize.

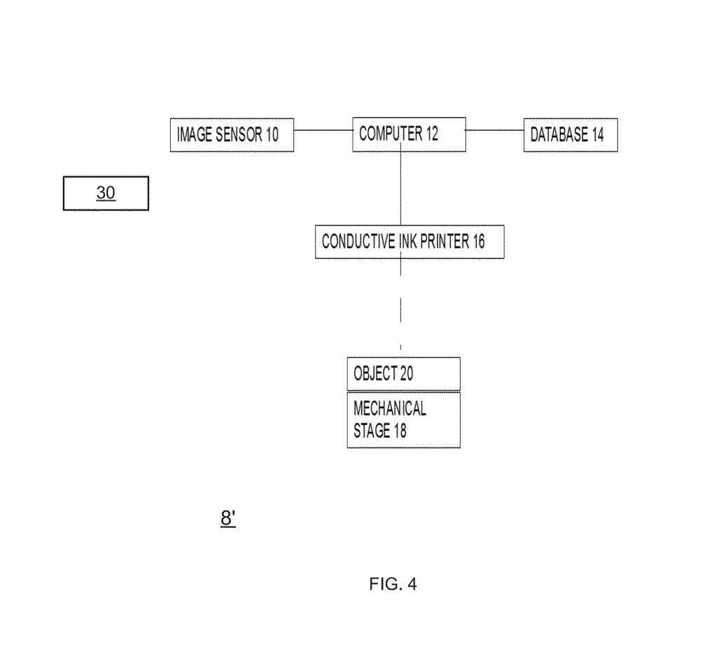

The conductive ink may need to undergo a treatment (such as a physical or a chemical treatment, for example thermal curing for improved applicable characteristics, photochemical curing for improved applicable characteristics, sintering, or drying under elevating temperature in range of 100° to 300° Celsius) process to become conductive—after printing. The treatment process may also include heating the printed conductive ink to hundreds of degrees, depending on formulations, ingredients and particle size. The treatment may also include radiating the conductive ink with radiation. FIG. 4 illustrates system 8′ according to an embodiment of the invention. System 8′ also includes a treatment module 30 for treating the ink.

Printing with conductive ink can include printing conductive lines/traces (on objects such as PCBs).

Referring back to FIGS. 2-3—the database 14 can store information on the nature and locations of missing copper.

The image sensor 10 can obtain images of areas in order to assess the nature of the existing patterns and supply the computer information to enable analysis

The computer 12 can process the images provided by the sensor and compare them to the information in database 14 and determine a manner in which conductive ink should be printed in the locations of the missing copper and send control signals to the printer.

The computer 12 can instruct the printer 16 to print one or multiple layers of conductive ink.

The computer 12 can also determine whether the missing conductive material defect can or cannot be treated by printing one or more conductive inks—if for example, the difference in the conductivity between the conductive material (for example—copper) and the conductive ink and the size or shape of the missing copper are too big to be effectively bridged by using the conductive ink. The computer 12 can also determine the viscosity of the ink in response to the size of the defect and, additionally or alternatively, time limitations imposed on the repair process.

Thus, the system can repair missing copper automatically and can compensate for line width\height\cut.

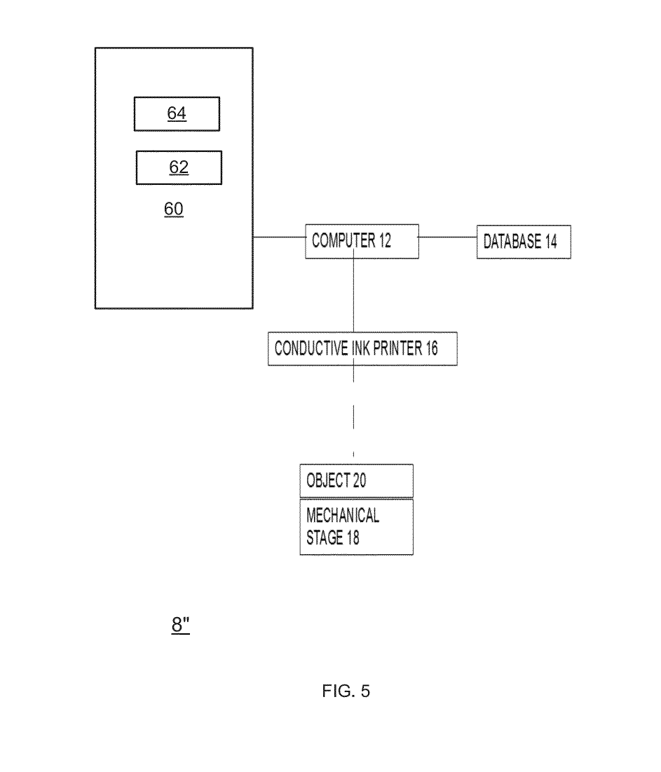

The system can be provided as a stand alone system or as an addition to verification and repair (CVR) or automatic optical inspection (AOI) systems that already include sensors, database and a computer. FIG. 5 illustrates a system 8″ according to an embodiment of the invention. System 8″ differs from system 8 by having a verification module 60 instead of image sensor 10. The verification module 60 includes its own image sensor 62 and a monitor 64 that is used to display images to a user. The same image sensor can be used for verification and repair purposes.

The combined inspection and repair system can eliminate load\unload panels required for transferring the object to the dedicated copper repair stations, can reduce the fixing time and allow fixing fine defects (small areas of missing copper) that cannot be repaired with current copper amending equipment.

Referring back to FIGS. 2 and 3, the computer 12 can get information from the (Job\Defect) database 14 on the defect location (and additionally or alternatively on a type of the defect) and what supposed to be in the panel at this place.

Once provided with suspect location information, the stage 18 can move object 20 so that the image sensor 10 can image the missing copper location, capture the image of the area and its vicinity, allow the computer 12 to analyze the images, build the fixing process to the specific defect, and allow the conductive ink printer 16 to fix the defect by printing conductive ink over the defect zone using a specific method.

The image sensor 10 can also grab one or more additional images after the fixing of the missing copper location in order to allow the computer 12 to verify that the defect is fixed.

Any one of systems 8, 8′ and 8″ can perform an iterative process of missing copper fixing until the missing copper defect is repaired.

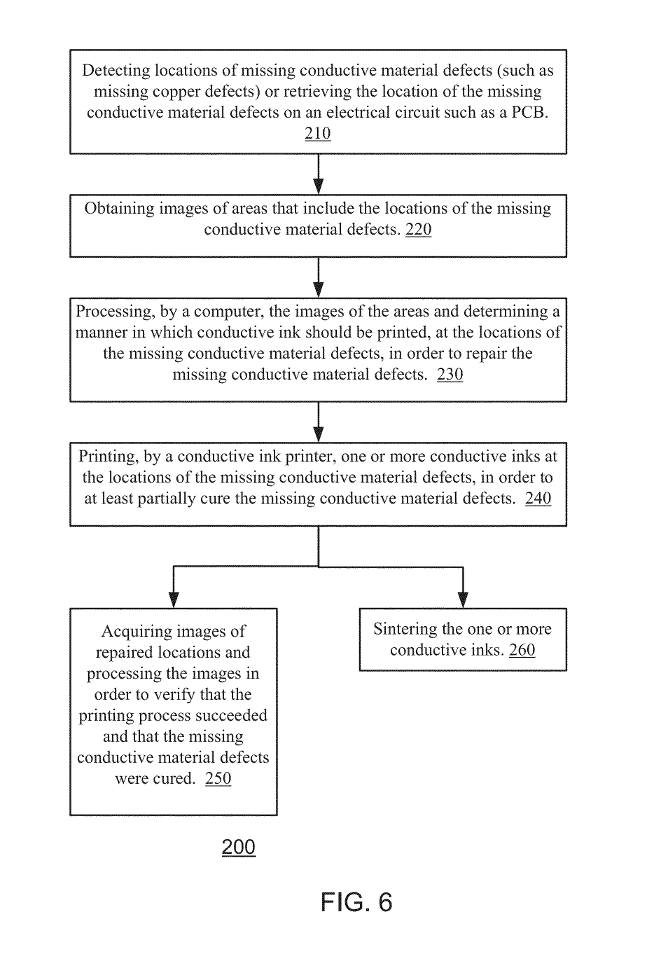

FIG. 6 illustrates a method 200 according to an embodiment of the invention.

Method 200 may start by stage 210 of detecting locations of missing conductive material defects (such as missing copper defects) or retrieving the location of the missing conductive material defects on an electrical circuit such as a PCB.

Stage 210 may be followed by stage 220 of obtaining images of areas that include the locations of the missing conductive material defects. Stage 220 may be followed by stage 230 of processing, by a computer, the images of the areas and determining a manner in which conductive ink should be printed, at the locations of the missing conductive material defects, in order to repair the missing conductive material defects. Stage 230 may include determining a defect correction scheme that defines the manner in which at least one of the missing conductive material defects should be amended.

Stage 230 may be followed by stage 240 of printing, by a conductive ink printer, one or more conductive inks at the locations of the missing conductive material defects, in order to at least partially treat the missing conductive material defects. Stage 240 may include printing multiple layers of conductive ink and at least partially treatment one or more layers of conductive ink before printing another layer of conductive ink in order to provide three dimensional conductive elements. The printing of stage 240 is responsive to the defect correction scheme.

Stage 240 may be followed by a verification stage 250 of acquiring images of repaired locations and processing the images in order to verify that the printing process succeeded and that the missing conductive material defects were treat. If it is determined that one or more additional printing sequence is required then stage 250 may be followed by stage 240.

Stage 240 may also be followed by stage 260 of sintering the one or more conductive inks.

According to an embodiment of the invention method 200 can be applied in scenarios that require the printing of conductive and non-conductive ink—in cases that both conductive and non-conductive materials are missing. In this case 230 may include processing, by a computer, images of areas that include missing material defects and determining a manner in which conductive ink and non-conductive ink should be printed, in order to repair the missing material defects.

Stage 230 may be followed by stage 240 of printing, by a conductive ink printer, one or more conductive inks and one more isolating inks in order to at least partially compensate for the missing material defects.

According to various embodiments of the invention the method may include printing one or more out of multiple materials having differing conductive characteristics in specific locations to functionally repair the defect. If the defect also includes missing isolating material then the method may also include printing an insulating ink.

In another embodiment, the location and nature of the defect may be determined by another device such as but not limited to an inspection machine.

In another embodiment of the method, one or more of the steps above may be performed by other systems while the coordination and communication is performed in one or more computing device.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A system, comprising:
a computer arranged to process images of areas of missing conductive material defects of an electrical circuit and to determine a defect correction scheme that defines a manner in which at least one of the missing conductive material defects should be amended; and
a conductive ink printer arranged to print conductive ink, in response to the defect correction scheme, to repair the at least one of the missing conductive material defects.

2. The system according to claim 1, further comprising an image sensor arranged to acquire the images of the areas of missing conductive materials defects.

3. The system according to claim 1, wherein the conductive ink printer is arranged to:
select, based upon the defect correction scheme, a selected conductive ink out of multiple conductive inks that differ from each other and are accessible to the conductive ink printer; and
print the selected conductive ink so as to treat one of the missing conductive material defects.

4. The system according to claim 3, wherein the conductive ink printer comprises multiple print heads, wherein different print heads are used for printing different conductive inks.

5. The system according to claim 3, wherein the different conductive inks differ from each other by conductivity.

6. The system according to claim 3, wherein the different conductive inks differ from each other by viscosity.

7. The system according to claim 3, wherein the different conductive inks differ from each other by at least one of a chemical characteristic and a physical characteristic.

8. The system according to claim 1, wherein the conductive ink printer is arranged to print multiple layers of at least one conductive ink to repair a missing conductive material defect.

9. The system according to claim 1, wherein the computer is arranged to declare a missing conductive material defect as non-repairable.

10. The system according to claim 1, further comprising a treatment module for at least partially treating a conductive ink that was printed on the electrical circuit.

11. The system according to claim 10, wherein the conductive ink printer is arranged to print multiple layers of at least one conductive ink to repair a missing conductive material defect; and
wherein the treatment module is arranged to at least partially treat a conductive ink layer before printing another conductive ink layer.

12. The system according to claim 1, further adapted to perform a verification process to determine that the one or more missing conductive material defect was repaired.

13. The system according to claim 1 wherein the conductive ink printer is further arranged to print conductive ink and non-conductive ink, in response to the defect correction scheme.

14. A method, comprising:
processing, by a computer, images of areas of missing conductive material defects of an electrical circuit and determining a defect correction scheme that defines a manner in which at least one of the missing conductive material defects should be amended; and
printing, by a conductive ink printer, conductive ink, in response to the defect correction scheme, to repair the at least one of the missing conductive material defects.

15. The method according to claim 14, further comprising acquiring, by an image sensor, the images of the areas of missing conductive materials.

16. The method according to claim 14, comprising:
selecting, based upon the defect correction scheme, a selected conductive ink out of multiple conductive inks that differ from each other and are accessible to the conductive ink printer, and
printing the selected conductive ink so as to treat one of the missing conductive material defects.

17. The method according to claim 16, wherein the printing comprises selecting a print head out of multiple print heads of the conductive ink printer, wherein different print heads are used for printing different conductive inks.

18. The method according to claim 16, wherein the different conductive inks differ from each other by conductivity.

19. The method according to claim 16, wherein the different conductive inks differ from each other by viscosity.

20. The method according to claim 16, wherein the different conductive inks differ from each other by at least one of a chemical characteristic and a physical characteristic.

21. The method according to claim 13, comprising printing multiple layers of at least one conductive ink to repair a missing conductive material defect.

22. The method according to claim 13, comprising declaring a missing conductive material defect as non-repairable.

23. The method according to claim 13, comprising at least partially treating a conductive ink that was printed on the electrical circuit.

24. The method according to claim 21, comprising printing multiple layers of at least one conductive ink to repair a missing conductive material defect; and at least partially treatment a conductive ink layer before printing another conductive ink layer.

25. The method according to claim 13, comprising performing a verification process to determine that the one or more missing conductive material defect was repaired.

26. The method according to claim 13 comprising printing conductive ink and non-conductive ink, in response to the defect correction scheme.
